(19) United States
(12) Patent Application Publication
(10) Pub. No.: US 2005/0110398 A1
(43) Pub. Date: May 26, 2005

(54) Full color OLED and method for fabricating the same

(76) Inventor: Jun-Yeob Lee, Seongnam-si (KR)

Correspondence Address: CHRISTIE, PARKER & HALE, LLP, PO BOX 7068, PASADENA, CA, 91109-7068, US

(21) Appl. No.: 10/980,090

(22) Filed: Nov. 2, 2004

(30) Foreign Application Priority Data
Nov. 25, 2003 (KR) 2003-84239

(51) Int. Cl. H05B 33/00

(52) U.S. Cl. 313/504; 313/506

(57) ABSTRACT

An organic light-emitting display is provided. The organic light-emitting display comprises a substrate having red, green and blue pixel regions, and first electrodes each located on the pixel regions. A red phosphorescent emission layer, a green phosphorescent emission layer and a blue fluorescent emission layer are respectively located on the first electrodes. A hole blocking layer is located on the red phosphorescent emission layer and the green phosphorescent emission layer but not the blue fluorescent emission layer. A second electrode is located on the hole blocking layer and the blue fluorescent emission layer.

### CROSS-REFERENCE TO RELATED APPLICATION

This application claims priority to and the benefit of Korean Patent Application No. 2003-84239, filed on Nov. 25, 2003, the entire disclosure of which is incorporated by reference.

### BACKGROUND OF THE INVENTION

1. Field of the Invention

The present invention relates to an organic light-emitting display and, more particularly, to a full color organic light-emitting display.

2. Description of the Related Art

Generally, an organic light-emitting display (OLED), which is an emissive display device, has advantages of wide viewing angle, good contrast and fast response time. These features have attracted much attention to OLEDs for next-generation displays.

The organic light-emitting display is composed of a substrate, an anode located on the substrate, an emission layer (EML) located on the anode, and a cathode located on the emission layer. When a voltage is applied between the anode and the cathode, a hole is injected from the anode into the emission layer, and an electron is injected from the cathode into the emission layer. The hole and the electron injected into the emission layer are combined in the emission layer to create excitons, and when the excitons decay from an excited state to a ground state, light is emitted.

In the organic light-emitting display, in order to implement a full color display of red (R), green (G), and blue (B), emission layers are formed corresponding to each color.

U.S. Pat. No. 6,281,634 discloses a full color organic light-emitting display in which the emission layers corresponding to R, G and B colors are formed, respectively. More specifically, this patent discloses a full color organic light-emitting display, in which the emission layers are independently formed for each R, G and B color and the remaining organic layers except the emission layers are commonly formed. The formation of common organic layers except the emission layers is desirable with respect to the process simplification, but it is difficult to optimize each different characteristic of the R, G, and B emission layers.

### SUMMARY OF THE INVENTION

According to an embodiment of the present invention, an organic light-emitting display and a method of fabricating the same are provided wherein each characteristic of the R, G and B emission layers can be optimized, and lifetime characteristics and luminous efficiency are improved.

In an embodiment of the present invention, an organic light-emitting display comprises a substrate having red, green and blue pixel regions; and a plurality of first electrodes, each located on a pixel region. A red phosphorescent emission layer, a green phosphorescent emission layer and a blue fluorescent emission layer are located on the first electrodes corresponding to the red, green, and blue pixel regions, respectively. A hole blocking layer is located on the red phosphorescent emission layer and the green phosphorescent emission layer but not the blue fluorescent emission layer. A second electrode is located on the hole blocking layer and the blue fluorescent emission layer.

The red phosphorescent emission layer may include an organic material having a carbazole unit as a host material. In one embodiment, the organic material having the carbazole unit is CBP (carbazole biphenyl). The red phosphorescent emission layer may further include at least one dopant material selected from the group consisting of PQIr, PQIr (acac), PlQIr (acac) and PtOEP.

The green phosphorescent emission layer may include an organic material having a carbazole unit as a host material. In one embodiment, the organic material having the carbazole unit is CBP (carbazole biphenyl). The green phosphorescent emission layer may also include a dopant material such as Ir(ppy)3.

The blue fluorescent emission layer may include at least one material selected from the group consisting of DPVBi, spiro-DPVBi, spiro-6P, distyryl-benzene(DSB), distyryl-arylene (DSA), PFO-based polymer and PPV-based polymer.

A HOMO (highly occupied molecular orbital) energy level of the hole blocking layer may be 5.5 to 6.9 eV. Further, the HOMO energy level of the hole blocking layer may be 5.7 to 6.7 eV.

The hole blocking layer may include at least one material selected from the group consisting of BCP, BAlq, CF—X and CF—Y. Further, the hole blocking layer may have a thickness of 30 to 100 Å.

The organic light-emitting display may further comprise a first charge transport layer and/or a first charge injection layer disposed between the first electrode and the emission layer. Further, the organic light-emitting display may comprise a second charge transport layer and/or a second charge injection layer disposed between the hole blocking layer and the second electrode, and disposed between the blue fluorescent emission layer and the second electrode.

According to another embodiment of the present invention, a method of fabricating an organic light-emitting display is provided comprising providing a substrate having red, green and blue pixel regions; forming first electrodes on the pixel regions; forming a red phosphorescent emission layer, a green phosphorescent emission layer and a blue fluorescent emission layer on the first electrodes corresponding to the red, green, and blue pixel regions, respectively; forming a hole blocking layer on the red phosphorescent emission layer and the green phosphorescent emission layer but not the blue fluorescent emission layer; and forming a second electrode on the hole blocking layer and the blue fluorescent emission layer.

The blue fluorescent emission layer, the red phosphorescent emission layer and the green phosphorescent emission layer may be formed by methods such as a laser induced thermal imaging (LITI) method or a vacuum deposition method using a fine metal mask, respectively.

The hole blocking layer may be formed by a vacuum deposition method using a fine metal mask.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a plan view illustrating an organic light-emitting display according to an embodiment of the present invention, in which only red (R), green (G) and blue (B) unit pixels of the organic light-emitting display are shown; and

FIG. 2 is a cross-sectional view for illustrating an organic light-emitting display and method of fabricating the same according to the present invention taken along the line I-I′ of FIG. 1.

### DETAILED DESCRIPTION

The present invention will now be described more fully hereinafter with reference to the accompanying drawings, in which certain embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, when one layer is located “on” the other layer or the substrate, it means that one layer can be directly formed on the other layer of the substrate or a third layer can be interposed therebetween. Like numbers refer to like elements throughout the specification.

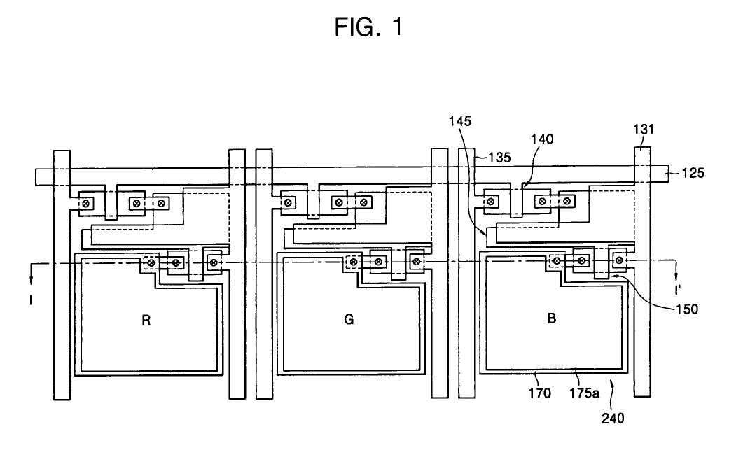

FIG. 1 is a plan view illustrating an organic light-emitting display according to an embodiment of the present invention, in which only red (R), green (G) and blue (B) unit pixels of the organic light-emitting display are shown.

Referring to FIG. 1, on organic light-emitting display includes a scan line 125 arranged in one direction, a data line 135 insulated with and crossing the scan line 125, and a common power supply line 131 insulated from and crossing the scan line 125 and in parallel with the data line 135. The crossing of the scan line 125 and the data line 135 defines a unit pixel. The scan line 125 serves to select a unit pixel to be driven, and the data line 135 serves to apply a data signal to the selected unit pixel.

A switching thin film transistor 140, a capacitor 145, and a pixel driving thin film transistor 150 are disposed in each unit pixel, wherein the switching thin film transistor 140 switches the data signal applied to the data line 135 according to a signal applied to the scan line 125, the capacitor 145 accumulates charges depending on a difference between the data signal, e.g., a data voltage, inputted through the switching thin film transistor 140 and a voltage applied to the common power supply line 131, and the pixel driving thin film transistor 150 receives the signal by the charges accumulated into the capacitor 145 causing a current to flow to an organic light emitting diode 240. The organic light emitting diode 240 is composed of a pixel electrode 170 and an emission layer electrically connected with the pixel electrode 170 through an opening 175a. A red phosphorescent emission layer is placed on the red unit pixel region R, a green phosphorescent emission layer is placed on the green unit pixel region G, and a blue fluorescent emission layer is placed on the blue unit pixel region B, respectively.

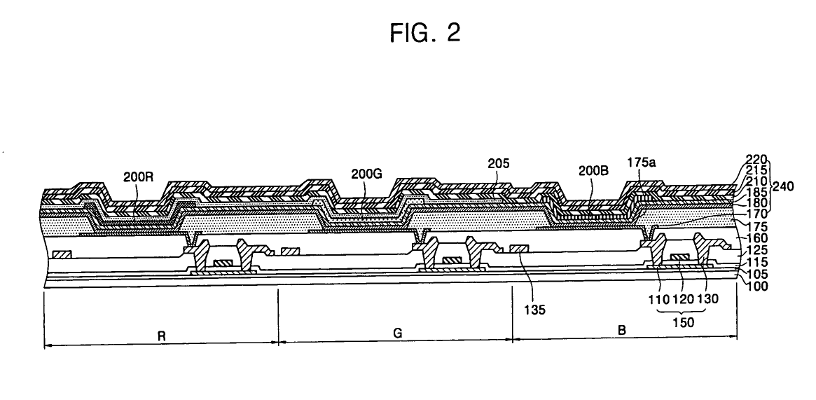

FIG. 2 is a cross-sectional view illustrating the organic light-emitting display of FIG. 1 taken along the line I-I′ of FIG. 1.

Referring to FIG. 2, a substrate 100 having red R, green G and blue B unit pixel regions is provided. It is desirable that a buffer layer 105 is formed on the substrate. An active layer 110, a gate insulating layer 115, a gate electrode 120, an interlayer 125 and source/drain electrodes 130 are formed on the buffer layer 105 by conventional methods. With this, a pixel driving thin film transistor 150 including the active layer 110, the gate electrode 120 and the source/drain electrodes 130 can be formed on each unit pixel region. A data line 135 is simultaneously formed while forming the gate electrode 120.

Subsequently, a passivation layer 160 is formed on the substrate where the pixel driving thin film transistor 150 is formed, and a via hole that exposes any one of the source/drain electrodes 130 of the pixel driving thin film transistor 150 is formed in the passivation layer 160. It is desirable that the passivation layer 160 is formed of a silicon nitride layer or a silicon oxynitride layer.

Next, a first electrode material is deposited on the substrate where the via hole is formed, and is patterned to form a first electrode 170 on the unit pixel region. The first electrode 170 can be either an anode or a cathode, and if the first electrode 170 is the anode, it can be formed either by using ITO (Indium Tin Oxide) or IZO (Indium Zinc Oxide), or by sequentially depositing AlNd and ITO. Otherwise, if the first electrode 170 is the cathode, it can be formed of Mg, Ca, Al, Ag, Ba or an alloy thereof.

Next, it is desirable that a pixel defining layer 175 having an opening 175a that exposes a portion of a surface of the first electrode 170 is formed on the first electrode 170. The pixel defining layer 175 having the opening 175a serves to define an emission region. Preferably, the pixel defining layer 175 is formed of a material selected from the group consisting of acrylic-based resins, BCB (benzocyclobutene) and PI (polyimide).

Next, it is desirable that a first charge injection layer 180 is formed on the first electrode 170 exposed in the opening 175a, and a first charge transport layer 185 is formed on the first charge injection layer 180. Alternatively, one of the first charge injection layer 180 and the first charge transport layer 185 can be omitted. The first charge injection layer 180 and the first charge transport layer 185 may be formed over all unit pixel regions of the substrate.

When the first electrode 170 is formed as an anode, the first charge injection layer 180 is formed using a hole injection material and the first charge transport layer 185 is formed using a hole transport material. It is desirable that the hole injection material is one selected from low molecular materials, such as CuPc, TNATA, TCTA and TDAPB, or polymeric materials, such as PANI, and PEDOT. Further, it is desirable that the hole transport material is selected from low molecular materials, such as NPB, NPD, TPD, s-TAD and MTADATA, etc., or polymeric material such as PVK.

When the first electrode 170 is formed as a cathode, the first charge injection layer 180 is formed using an electron injection material, and the first charge transport layer 185 is formed using an electron transport material. It is desirable that the electron injection material is selected from the group consisting of Alq3, Ga complex, PBD and LiF. Further, it is desirable that the electron transport material is selected from polymeric materials such as PBD, TAZ and spiro-PBD, or low molecular materials such as Alq3, Balq and Salq.

Next, emission layers are formed on the first charge transport layer 185, wherein a red phosphorescent emission layer 200R that emits red phosphorescence is formed on the red unit pixel region R, a green phosphorescent emission layer 200G that emits green phosphorescence is formed on the green unit pixel region G, and a blue fluorescent emission layer 200B that emits blue fluorescence is formed on the blue unit pixel region B.

While driving the organic light-emitting display, an electron and a hole are recombined in the emission layer to create excitons, and when the excitons decay from an excited state to a ground state, light is emitted. With respect to the exciton generation, singlet excitons and triplet excitons are created in a ratio of 1 to 3.

When the emission layer is formed of a fluorescent material, the transition to the ground state of the triplet exciton is prevented and only the singlet exciton contributes to the emission, so that quantum efficiency is just 25%. However, while forming the emission layer, when an organic metal complex having a heavy metal, such as Ir or Pt in the center is used as a phosphorescent dopant material, both the singlet exciton and the triplet exciton contribute to the emission, thereby improving the internal quantum efficiency. This leads to an increase of the luminous efficiency.

Therefore, in implementing a full color organic light-emitting display, it is advantageous to form all of the R, G and B emission layers with a phosphorescent material in terms of the luminous efficiency. However, when the blue emission layer is formed of the phosphorescent material, it has been found that its lifetime is very short.

Accordingly, a red emission layer and a green emission layer are formed of phosphorescent emission layers 200R, 200G having good lifetime and efficiency characteristics, and a blue emission layer is formed of a fluorescent emission layer 200B having good lifetime characteristic, thereby optimizing both the lifetime feature and the luminous efficiency of the organic light-emitting display.

The red phosphorescent emission layer 200R may include an organic material having a carbazole unit as a host material. The organic material having the carbazole unit may be CBP (carbazole biphenyl). Further, the red phosphorescent layer 200R may include at least one material selected from the group consisting of PlQIr (acac) (bis(1-phenylisoquinoline)acetylacetonate iridium), PQIr(acac) (bis(1-phenylquinoline)acetylacetonate iridium), PQIr (tris(1-phenylquinoline) iridium) and PtOEP(octaethylporphyrin platinum), as a dopant material.

The green phosphorescent emission layer 200G may include an organic material having a carbazole unit as a host material. The organic material having the carbazole unit may be CBP (carbazole biphenyl). Further, the green phosphorescent layer 200G may include Ir(ppy)3 (fac tris(2-phenylpyridine)iridium) as a dopant material.

The blue fluorescent emission layer 200B may include at least one material selected from the group consisting of DPVBi, spiro-DPVBi, spiro-6P, distyryl-benzene (DSB), distyryl-arylene (DSA), PFO-based polymers and PPV-based polymers.

The formation of the emission layers 200R, 200G and 200B by each unit pixel region is performed by a vacuum deposition method using a fine metal mask and a laser induced thermal imaging method.

Next, a hole blocking layer 205 is formed on the red and the green phosphorescent emission layers 200R, 200G, but not on the blue fluorescent emission layer 200B. For the phosphorescent emission layer, the lifetime and the diffusion length of the excitons are longer than for the excitons of the fluorescent emission layer. Therefore, the hole blocking layer 205 is formed on the red and green phosphorescent emission layers 200R, 200G, so that the diffusion of the excitons from the emission layers, that is, the hole movement is blocked. With this, the hole blocking layer 205 is not formed on the blue fluorescent emission layer 200B, so that the driving voltage can be reduced.

Preferably, the hole blocking layer 205 is formed of a material whose HOMO (highly occupied molecular orbital) energy level is 5.5 to 6.9 eV. More preferably, the hole blocking layer 205 is formed of a material whose HOMO energy level is 5.7 to 6.7 eV. Exemplary materials for the hole blocking layer 205 include materials or combinations of materials selected from the group consisting of BCP (2,9-dimethyl-4,7-diphenyl-1,10-phenanthroline), BAlq (Aluminum(III)bis(2-methyl-8-quinolinato)-4-phenylphenolate), CF—X(C₆₀F₄₂) and CF—Y(C₆₀F₄₂).

Preferably, the hole blocking layer 205 on the red and green emission layers 200R, 200G is formed by a vacuum deposition method using a fine metal mask. Furthermore, the hole blocking layer 205 is preferably formed to a thickness of 30 to 100 Å. When the thickness of the hole blocking layer 205 is below 30 Å, it is difficult to suppress inflow of holes from the red and green phosphorescent emission layers 200R, 200G, and when the thickness of the hole blocking layer 205 is above 100 Å, an excessive increase in the driving voltage can be required.

Next, it is desirable that a second charge transport layer 210 is formed on the hole blocking layer 205 and the blue emission layer 200B, and a second charge injection layer 215 is formed on the second charge transport layer 210. Alternatively, one of the second charge transport layer 210 and the second charge injection layer 215 can be omitted. When the first electrode 170 is formed as an anode, the second charge transport layer 210 is formed of an electron transport material, and the second charge injection layer 215 is formed of an electron injection material. Otherwise, when the first electrode 170 is formed as a cathode, the second charge transport layer 210 is formed of a hole transport material and the second charge injection layer 215 is formed of a hole injection material.

Next, a second electrode 220 is formed on the second charge injection layer 215. When the first electrode 170 is formed as an anode, the second electrode 220 is formed as a cathode, and when the first electrode 170 is formed as a cathode, the second electrode 220 is formed as an anode. The first electrode 170, the second electrode 220 and the organic layers interposed therebetween form the organic light emitting diode 240.

An example will now be presented to help the understanding of the present invention. However the following example is just for aiding the understanding of the present invention, and not for limiting the present invention to the specific example.

### EXAMPLE

A first electrode was formed of ITO on a substrate, and a hole injection layer with a thickness of 10 nm was formed of CuPc (copper phthalocyanine) on the first electrode under a vacuum of 10⁻⁶ Torr. A hole transport layer having a thickness of 50 nm was formed of NPD (N,N′-di(1-naphtyl)-N,N′-diphenylbenzidine) on the hole injection layer under a vacuum of 10⁻⁶ Torr. For each unit pixel region, a red phosphorescent emission layer, a green phosphorescent emission layer and a blue fluorescent emission layer were formed on the hole transport layer using a fine metal mask, wherein the red phosphorescent emission layer was formed to a thickness of 30 nm by vacuum-codepositing 10 wt. % PQIr(tris(1-phenylquinoline) iridium) as a dopant material and CBP as a host material. The green phosphorescent emission layer was formed to a thickness of 30 nm by vacuum-codepositing 5 wt. % Ir(ppy)3 as a dopant material and CBP as a host material. The blue fluorescent emission layer was formed to a thickness of 30 nm by vacuum-codepositing 5 wt. % IDE105(Idemitsu Co.) as a dopant material and IDE120(Idemitsu Co.) as a host material. Subsequently, the hole blocking layer was formed to a thickness of 5 nm using BAlq(biphenoxy-bi(8-quinolinolato)aluminum) on the red and green phosphorescent emission layers, but not on the blue fluorescent emission layer, using a fine metal mask. An electron transport layer with a thickness of 20 nm was formed on the hole blocking layer and the blue fluorescent emission layer, using Alq3 (tris(8-quinolinolato)aluminum) under a vacuum of 10⁻⁶ Torr. An electron injection layer with a thickness of 1 nm was formed on the electron transport layer using LiF, and a cathode with a thickness of 300 nm was formed on the electron injection layer, using Al. Next, the above structure was encapsulated by a metal can or barium oxide to fabricate an organic light-emitting display.

### COMPARATIVE EXAMPLE

An organic light-emitting display was fabricated by the same method as the above example, except that a hole blocking layer with a thickness of 5 nm was formed of BAlq(biphenoxy-bi(8-quinolinolato)aluminum) on the red phosphorescent emission layer, the green phosphorescent emission layer and the blue fluorescent emission layer.

Efficiency, driving voltages and color coordinates were measured for the organic light-emitting display according to the example and the comparative example. The results are shown in Table 1.

TABLE 1

| | | Luminous | | |
|---|---|---|---|---|
| | Unit | efficiency | Driving voltage (V) | Color |
| | pixel | (cd/A) | @ 500 cd/m² | coordinates |
| Example | R | 10.0 | 6.8 | 0.62, 0.37 |
| | G | 24.5 | 6.5 | 0.29, 0.63 |
| | B | 5.5 | 6.5 | 0.15, 0.13 |
| Comparative | R | 10.0 | 6.8 | 0.62, 0.37 |
| example | G | 24.5 | 6.5 | 0.29, 0.63 |
| | B | 5.2 | 7.0 | 0.15, 0.15 |

Referring to Table 1, comparing the Comparative Example where the hole blocking layer was formed on the blue fluorescent emission layer to the Example where the hole blocking layer was not formed on the blue fluorescent emission layer, the Example showed improved luminous efficiency and reduced driving voltages as well as optimized color coordinates in the blue unit pixel.

As described above, according to the present invention, phosphorescent emission layers with good luminous efficiency are used for red and green colors and a fluorescent emission layer with good lifetime characteristics is used for a blue color, thereby optimizing both the lifetime feature and the luminous efficiency of the organic light-emitting display. With this, a hole blocking layer is formed on the red and green phosphorescent emission layers, but not on the blue fluorescent emission layer, thereby improving the luminous efficiency of the red and green phosphorescent layers, and suppressing the increase of the driving voltage for the blue fluorescent layer. Further, the improvement of the luminous efficiency and the optimization of the color coordinates can be obtained for the blue fluorescent emission layer.

1. An organic light-emitting display comprising:
a substrate having red, green and blue pixel regions;
a plurality of first electrodes located on the pixel regions;
a red phosphorescent emission layer, a green phosphorescent emission layer and a blue fluorescent emission layer, each located on the first electrodes and corresponding to the respective red, green and blue pixel regions;
a hole blocking layer located on the red phosphorescent emission layer and the green phosphorescent emission layer, but not the blue fluorescent emission layer; and
a second electrode located on the hole blocking layer and the blue fluorescent emission layer.

2. The organic light-emitting display according to claim 1, wherein the red phosphorescent emission layer includes an organic material having a carbazole unit as a host material.

3. The organic light-emitting display according to claim 2, wherein the organic material is CBP (carbazole biphenyl).

4. The organic light-emitting display according to claim 1, wherein the red phosphorescent emission layer includes a dopant material selected from the group consisting of PQIr, PQIr(acac), PlQIr(acac), PtOEP and combinations thereof.

5. The organic light-emitting display according to claim 1, wherein the green phosphorescent emission layer includes an organic material having a carbazole unit as a host material.

6. The organic light-emitting display according to claim 5, wherein the organic material is CBP (carbazole biphenyl).

7. The organic light-emitting display according to claim 1, wherein the green phosphorescent emission layer includes Ir(ppy)3 as a dopant material.

8. The organic light-emitting display according to claim 1, wherein the blue fluorescent emission layer includes a material selected from the group consisting of DPVBi, spiro-DPVBi, spiro-6P, distyryl-benzene(DSB), distyryl-arylene (DSA), PFO-based polymers, PPV-based polymers and combinations thereof.

9. The organic light-emitting display according to claim 1, wherein the hole blocking layer has a HOMO(highly occupied molecular orbital) energy level of from 5.5 to 6.9 eV.

10. The organic light-emitting display according to claim 9, wherein the HOMO energy level of the hole blocking layer is from 5.7 to 6.7 eV.

11. The organic light-emitting display according to claim 1, wherein the hole blocking layer includes a material selected from the group consisting of BCP, BAlq, CF—X, CF—Y and combinations thereof.

12. The organic light-emitting display according to claim 1, wherein the hole blocking layer has a thickness of from 30 to 100 Å.

13. The organic light-emitting display according to claim 1, further comprising:
at least one of a first charge transport layer and a first charge injection layer disposed between the first electrode and the emission layer.

14. The organic light-emitting display according to claim 1, further comprising:
at least one of a second charge transport layer and a second charge injection layer disposed between the blue fluorescent emission layer and the second electrode or between the hole blocking layer and the second electrode

15. A method of fabricating an organic light-emitting display, comprising:
providing a substrate having red, green and blue pixel regions;
forming first electrodes over the pixel regions;
forming a red phosphorescent emission layer, a green phosphorescent emission layer and a blue fluorescent emission layer located on the first electrodes and corresponding to the respective red, green and blue pixel regions;
forming a hole blocking layer on the red phosphorescent emission layer and the green phosphorescent emission layer but not the blue fluorescent emission layer; and
forming a second electrode on the hole blocking layer and the blue fluorescent emission layer.

16. The method according to claim 15, wherein the blue fluorescent emission layer, the red phosphorescent emission layer and the green phosphorescent emission layer are formed by a method selected from the group consisting of laser induced thermal imaging (LITI) methods and vacuum deposition methods using a fine metal mask.

17. The method according to claim 15, wherein the hole blocking layer is formed by a vacuum deposition method using a fine metal mask.
